(19) United States
(12) Patent Application Publication
(10) Pub. No.: US 2016/0033879 A1
(43) Pub. Date: Feb. 4, 2016

(54) METHODS AND CONTROLLERS FOR CONTROLLING FOCUS OF ULTRAVIOLET LIGHT FROM A LITHOGRAPHIC IMAGING SYSTEM, AND APPARATUSES FOR FORMING AN INTEGRATED CIRCUIT EMPLOYING THE SAME

(71) Applicant: GLOBALFOUNDRIES, Inc., Grand Cayman (KY)

(72) Inventors: Sudharshanan Raghunathan, Mechanicville, NY (US); Obert Reeves Wood II, Loudonville, NY (US); Moshe E. Preil, Sunnyvale, CA (US)

(21) Appl. No.: 14/446,784

(22) Filed: Jul. 30, 2014

(51) Int. Cl. G03F 7/20

(52) U.S. Cl. CPC G03F 7/70641

(57) ABSTRACT

Methods and controllers for controlling focus of ultraviolet light produced by a lithographic imaging system, and apparatuses for forming an integrated circuit employing the same are provided. In an embodiment, a method includes providing a wafer having a resist film disposed thereon. The resist film is patterned through illumination of a lithography mask with ultraviolet light at an off-normal incidence angle with a first test pattern formed at a first pitch and a second test pattern formed at a second pitch different from the first pitch. Non-telecentricity induced shift of the first and second test patterns is measured to produce relative shift data using a measurement device. Focus of the ultraviolet light is adjusted based upon comparison of the relative shift data to a pre-determined correlation between the non-telecentricity induced shift of the first and second test patterns as a function of focus error.

### TECHNICAL FIELD

The technical field generally relates to methods of controlling the focus of ultraviolet (UV) light from a lithographic imaging system, apparatuses for forming an integrated circuit that employ the method, and controllers programmed to control the focus of the ultraviolet light. More particularly, the invention relates to methods, apparatuses, and controllers that employ test patterns to adjust the focus of ultraviolet light from the lithographic imaging system.

### BACKGROUND

Focus control is an important consideration in lithography techniques to ensure proper pattern formation in semiconductor devices. Focus control generally involves focus monitoring to provide feedback for adjusting the focus of UV light from a lithographic imaging system on the semiconductor device. The lithographic imaging system generally includes a light source, a collector (also known as a condenser lens system), a lithography mask (also known as a reticle), and an objective lens (also known as an imaging or reduction lens). In lithography techniques that involve extremely small scale of illuminated patterns, such as extreme ultraviolet (EUV) lithography, focus control is often challenging. Focus control is primarily dictated by the critical dimensions of the pattern as well as the thicknesses of the resist films that are employed during patterning, and focus control and overlay budgets in EUV lithography are also generally interdependent. As pattern critical dimensions and layer thicknesses decrease, focus control must also become more precise and accurate. Additionally, EUV lithography generally involves illumination of a lithography mask at an off-incidence angle. Due to the off-incidence angle, the best focus of UV light from the lithographic imaging system will vary depending on the size and pitch of the pattern being printed and the location of the pattern within an exposure field. As such, the best focus is variable across the exposure field.

Conventional focus monitoring techniques generally employ a metrology technique called scatterometry whereby a measured change in sidewall angle within patterns in a photoresist can be correlated to the focus of the UV light that is employed for pattern formation. However, conventional scatterometry techniques are sensitive to thickness and film properties of the photoresist. In particular, as the layer thicknesses of the photoresist decrease, scatterometry becomes less effective for focus monitoring because the measurement of sidewall angle becomes more difficult.

Phase shift focus monitoring is another conventional technique that employs a phase grating structure to monitor the focus of the light that is employed for pattern formation. The phase grating structure is a photomask that generally includes a box-in-box pattern, containing an inner nested box structure and an outer nested box structure. Using the phase grating structure, a shift in focus of the UV light manifests as an equal and opposite shift in the resulting inner and outer box patterns formed in a photoresist. However, the phase shift focus monitor does not provide adequate sensitivity for EUV lithography and is difficult to implement due to the stringent requirements that must be met during its fabrication.

Accordingly, it is desirable to provide improved methods of monitoring the focus of UV light from a lithographic imaging system, especially in lithography techniques such as EUV lithography, with the improved methods providing adequate sensitivity to changes in focus and with the improved methods not dependent on the thickness of the photoresist employed during lithography. Furthermore, other desirable features and characteristics of the present invention will become apparent from the subsequent detailed description and the appended claims, taken in conjunction with the accompanying drawings and this background.

### BRIEF SUMMARY

Methods and controllers for controlling the focus of ultraviolet light produced by a lithographic imaging system, and apparatuses for forming an integrated circuit employing the same are provided. In an embodiment, a method for controlling the focus of ultraviolet light produced by a lithographic imaging system includes providing a wafer having a resist film disposed thereon. The resist film is patterned through illumination of a lithography mask with ultraviolet light at an off-normal incidence angle with a first test pattern formed at a first pitch and a second test pattern formed at a second pitch different from the first pitch. Non-telecentricity induced shift of the first test pattern and the second test pattern is measured to produce relative shift data using a measurement device. Focus of the ultraviolet light is adjusted based upon comparison of the relative shift data to a pre-determined correlation between the non-telecentricity induced shift of the first test pattern and the second test pattern as a function of focus error.

In another embodiment, an apparatus for forming an integrated circuit includes a lithographic imaging system, a controller, and a measurement device. The lithographic imaging system is configured to pattern a resist film on a wafer through illumination of a lithography mask at an off-normal incidence angle. The controller is programmed to control focus of ultraviolet light produced by the lithographic imaging system. The controller is programmed with instructions to pattern the resist film on the wafer using the ultraviolet light produced by the lithographic imaging system through illumination of the lithography mask at the off-normal incidence angle with a first test pattern formed at a first pitch and a second test pattern formed at a second pitch different from the first pitch, analyze relative shift data obtained from measuring non-telecentricity induced shift of the first test pattern and the second test pattern, and adjust the focus of the ultraviolet light based upon a comparison of the relative shift data to a pre-determined correlation between the non-telecentricity induced shift of the first test pattern and the second test pattern as a function of focus error. The measurement device is configured to measure the non-telecentricity induced shift of the first test pattern and the second test pattern to produce the relative shift data.

In another embodiment, a controller is programmed to control focus of ultraviolet light produced by a lithographic imaging system. The controller is programmed with instructions to pattern a resist film on a wafer using the ultraviolet light produced by the lithographic imaging system through illumination of a lithography mask at an off-normal incidence angle with a first test pattern formed at a first pitch and a second test pattern formed at a second pitch different from the first pitch, analyze relative shift data obtained from measuring non-telecentricity induced shift of the first test pattern and the second test pattern, and adjust focus of the ultraviolet light based upon comparison of the relative shift data to a pre-determined correlation between the non-telecentricity induced shift of the first test pattern and the second test pattern as a function of focus error.

### BRIEF DESCRIPTION OF THE DRAWINGS

The various embodiments will hereinafter be described in conjunction with the following drawing figures, wherein like numerals denote like elements, and wherein:

FIG. 1 illustrates a diagram of an apparatus for forming an integrated circuit in accordance with an embodiment;

FIG. 2 is a schematic representation of a first test pattern and a second test pattern in accordance with an embodiment;

FIG. 3 is a graph illustrating a correlation of pattern shift within two different test patterns formed at different pitches and focus error in accordance with an embodiment;

FIG. 4 is a schematic representation of a first test pattern and a second test pattern in accordance with an alternative embodiment;

FIG. 5 is a schematic representation of a first test pattern and a second test pattern in accordance with another alternative embodiment; and

FIG. 6 is a schematic representation of a first test pattern and a second test pattern in accordance with another alternative embodiment.

### DETAILED DESCRIPTION

The following detailed description is merely exemplary in nature and is not intended to limit the invention or the application and uses of the invention. Furthermore, there is no intention to be bound by any theory presented in the preceding background or the following detailed description.

Methods of controlling focus of ultraviolet (UV) light produced by a lithographic imaging system, apparatuses for forming an integrated circuit employing the method, and controllers programmed to control focus of UV light are provided herein. The methods of monitoring focus of the UV light are particularly suited for lithography techniques that involve extremely small scale of illuminated patterns, such as extreme ultraviolet (EUV) lithography that illuminates a lithography mask at an off-normal incidence angle, and the methods provide adequate sensitivity to changes in focus and are not dependent on a thickness of the photoresist employed during lithography. In particular, non-telecentricity is a recognized phenomenon that impacts printing performance in many photolithography techniques, especially lithography techniques that illuminate a lithography mask at an off-normal incidence angle. The non-telecentricity phenomenon occurs when the UV light is out of focus due to oblique illumination of the lithography mask and off-axis reflection of light rays from different vertical positions of the lithography mask. The non-telecentricity phenomenon results in shift and bias of the patterned features on the wafer up to several nanometers with respect to their target dimension. Such shift in the patterned features may be referred to as a non-telecentricity induced shift. In accordance with the methods, apparatuses, and controllers described herein, non-telecentricity induced shift of a first test pattern and a second test pattern having different pitches is measured, and such measurement is employed in a comparison to a pre-determined correlation of non-telecentricity induced shift of the first test pattern and the second test pattern as a function of focus error. Because non-telecentricity shift varies for printed patterns having different pitches, differences in non-telecentricity induced shift in the first test pattern and the second test pattern may be employed to provide a direct correlation to focus error. Based upon the pre-determined correlation of non-telecentricity induced shift of a given first test pattern and second test pattern, focus error can be determined for first test patterns and second test patterns formed on wafers during integrated circuit fabrication, thereby allowing focus error to be expediently and accurately determined on product wafers independent of photoresist thickness.

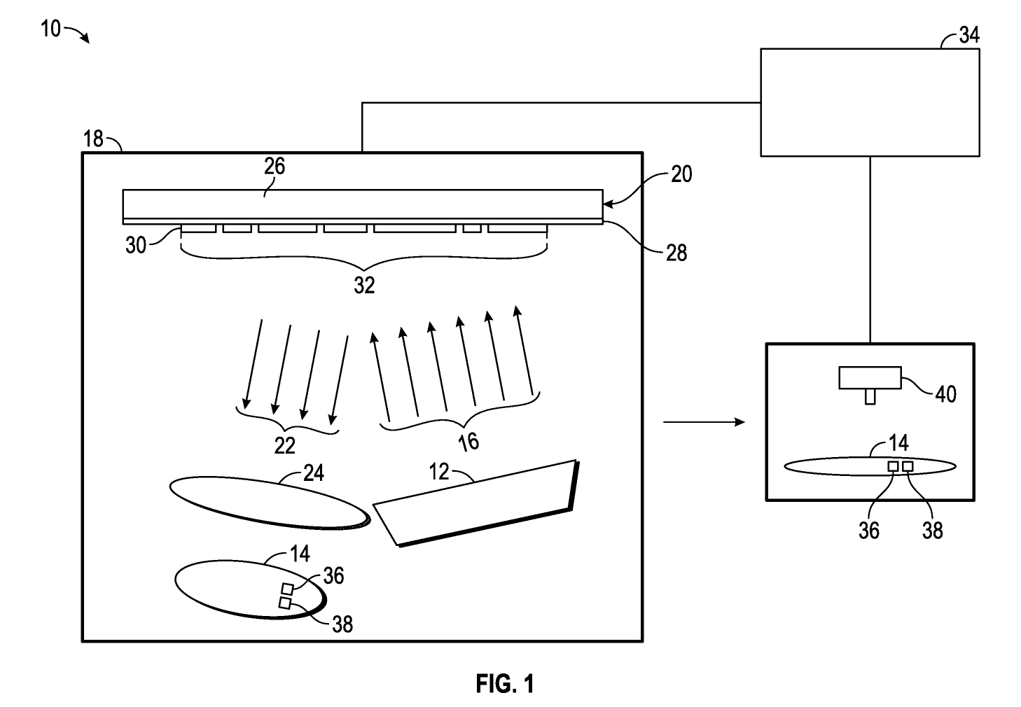

An exemplary embodiment of an apparatus 10 for forming an integrated circuit will now be described with reference to FIG. 1. The apparatus 10 includes a lithographic imaging system 18 that is configured to pattern a resist film on a wafer 14 through illumination of a lithography mask 20 at an off-normal incidence angle using UV light 16 to produce reflected UV light 22. In embodiments and as shown in FIG. 1, the lithographic imaging system 18 includes a light source 12, the lithography mask 20, and one or more optics 24 (i.e., objective lens). Although not shown, the lithographic imaging system may further include a collector. An “off-normal incidence angle”, as referred to herein, means that the UV light 16 is directed at a non-perpendicular angle relative to a surface of the lithography mask 20. In embodiments, the lithographic imaging system 18 is an extreme ultraviolet (EUV) lithographic imaging system, although it is to be appreciated that any lithographic imaging system may be employed that patterns a resist film through illumination of a lithography mask 20 with UV light 16 at an off-normal incidence angle. In this embodiment, the lithography mask 20 is an EUV reflective mask and includes a substrate 26, a reflective film 28, and an absorbent film 30.

As shown in FIG. 1, the reflective film 28 is disposed over the substrate 26 and can include a multilayer film for reflecting UV light 16. For example, in embodiments, the reflective film 28 includes a number of alternating layers of molybdenum and silicon. In embodiments, the substrate 26 includes fused silica or other suitable material having a low thermal expansion co-efficient and has a thickness equal to approximately ¼ inch, for example. As also shown in FIG. 1, the absorbent film 30 is disposed over the reflective film 28 and includes pattern 32. The absorbent film 30 may include a suitable UV absorbing material as known in the art. The pattern 32, which can be lithographically transferred to the wafer 14 by the reflected UV light 22, can be formed by selectively removing portions of the absorbent film 30 to expose corresponding portions of the reflective film 28. During lithographic processing of the wafer 14, only reflected UV light 22 produced by the UV light 16 striking exposed portions of the reflective film 28 is directed to the wafer 14 by the optics 24.

Referring to FIG. 1, the apparatus 10 further includes a controller 34 that is programmed to control focus of UV light 16 produced by the light source 12. In embodiments, the controller 34 includes a processor programmed with instructions for operating the lithographic imaging system 18, either automatically or when inputs are entered by a user. Among other functionality, the controller 34 is programmed with instructions to pattern the resist film on the wafer 14 using the UV light 16 produced by the lithographic imaging system 18. For purposes of controlling focus of the UV light 16, the controller 34 is programmed with instructions to pattern the resist film with a first test pattern 36 formed at a first pitch and a second test pattern 38 formed at a second pitch that is different from the first pitch. “Pitch”, as referred to herein, means a distance between identical points in two neighboring features of the respective patterns. As described in further detail below, non-telecentricity induced shift of the first test pattern 36 and the second test pattern 38 having different pitches may be employed in a comparison to a pre-determined correlation of non-telecentricity induced shift of the first test pattern 36 and the second test pattern 38 as a function of focus error. Various configurations for the first test pattern 36 and the second test pattern 38 are described in detail below. The controller 34 is further programmed to analyze relative shift data obtained from measuring non-telecentricity induced shift of the first test pattern 36 and the second test pattern 38. The controller 34 is further programmed to adjust focus of the UV light 16 based upon comparison of the relative shift data to a pre-determined correlation between the non-telecentricity induced shift of the first test pattern 36 and the second test pattern 38 as a function of focus error.

The apparatus 10 further includes a measurement device 40 that is configured to measure the non-telecentricity induced shift of the first test pattern 36 and the second test pattern 38 to produce the relative shift data. Measurement of the non-telecentricity induced shift involves measurement of a spacing between features on the nanometer scale, and suitable measurement devices 40 include those capable of measurements on the Angstrom scale. Examples of suitable measurement devices 40 include, but are not limited to, those chosen from a scanning electron micrograph device, an overlay measurement device, or a scatterometry overlay metrology device. It is to be appreciated that certain configurations of the first test pattern 36 and the second test pattern 38 may be desirable for certain measurement devices 40 as appreciated by those of skill in the art.

A method of controlling the focus of ultraviolet light produced by a lithographic imaging system, such as the lithographic imaging system 18 of the apparatus 10 shown in FIG. 1, will now be described. In accordance with the exemplary method, a wafer 14 is provided having a resist film disposed thereon, as is conventional during patterning through photolithography. However, in embodiments, EUV lithography is carried out and the resist film has a thickness of less than about 60 nm. With such small thicknesses of the resist film, scatterometry is ineffective to determine focus error, whereas the methods described herein are effective independent of resist film thickness. Further, in embodiments, the wafer 14 is a product wafer upon which an integrated circuit is to be formed. In this regard, focus of the UV light 16 can be controlled in accordance with the methods described herein during integrated circuit fabrication, without employing dedicated testing wafers. Use of product wafers is possible in accordance with the described methods because pattern shifts based upon the non-telecentricity phenomenon are employed to determine focus error, and measurements can be conducted with conventional optical measurement instruments. Further, a variety of different test patterns can be employed based upon space constrains and location of the test patterns on the wafer is not limited.

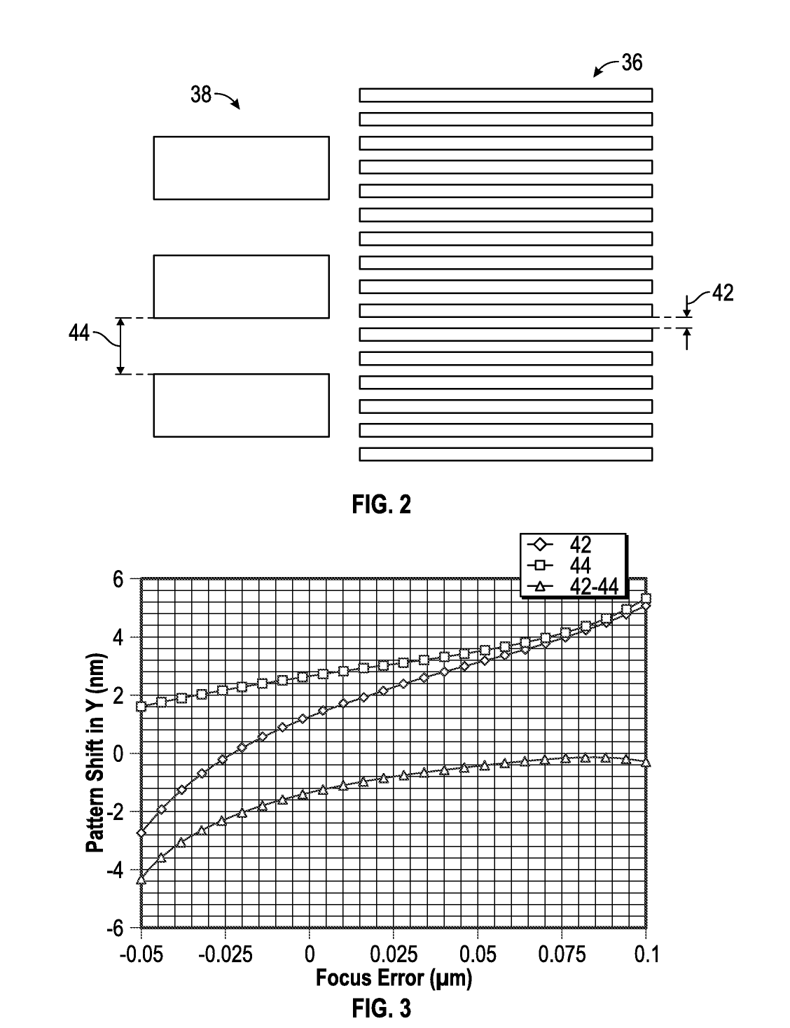

The resist film is patterned through illumination of the lithography mask 20 at an off-normal incidence angle, with the first test pattern 36 formed at a first pitch and the second test pattern 38 formed at a second pitch different from the first pitch. For example, FIG. 2 shows an embodiment of the first test pattern 36 and the second test pattern 38 formed at different pitches. In embodiments, the first pitch is different from the second pitch by a magnitude of at least 3×, such as at least 5×, such as at least 8×, such as from about 3× to about 12×. For example, in embodiments, the first pitch is from about 40 to about 50 nm, and the second pitch is from about 150 to about 500 nm. In one specific embodiment, the first pitch is about 44 nm and the second pitch is about 400 nm. In embodiments, device features (i.e., features formed in accordance with fabrication of the integrated circuit and not solely for testing purposes) may be patterned as the first test pattern 36 and the second test pattern 38, provided that the device features are sufficiently close together to enable optical measurement on the Angstrom scale. In other embodiments the first test pattern 36 and the second test pattern 38 are formed as independent features from patterned device features, with the first test pattern 36 and the second test pattern 38 only employed for testing purposes.

For purposes of determining focus error, a non-telecentricity induced shift of the first test pattern 36 and the second test pattern 38 is measured to produce relative shift data using, e.g., the measurement device 40 shown in FIG. 1. To produce the relative shift data, various measurements of the first test pattern 36 and the second test pattern 38 can be made and the difference between the measurements determined. For example, in an embodiment and as shown in FIG. 2, a first measurement 42 is taken between features in the first test pattern 36, and a second measurement 44 is taken between features in the second test pattern 38. The second measurement 44 is subtracted from the first measurement 42 to produce the relative shift data.

The relative data shift is compared to a pre-determined correlation between non-telecentricity induced shift of the first test pattern 36 and the second test pattern 38 as a function of focus error, thereby enabling focus error to be determined based upon the relative shift data measured for the particular first measurement 42 and the second measurement 44. For example, to generate the data in the graph of FIG. 3, an array of first test patterns and second test patterns is patterned with known focus errors and first measurements 42 and second measurements 44 are taken for each pattern at the known focus error. The array may be patterned on a focus meander wafer (not shown). The second measurements 44 are subtracted from the first measurements 42 at the known focus errors to produce the pre-determined correlation between non-telecentricity induced shift of the first test pattern and the second test pattern as a function of focus error. As shown in FIG. 3, while pattern shifts within the first pattern and the second pattern vary in magnitude and are unpredictable across different focus errors for patterns of different pitch, the difference between patterns shifts provides a direct, predictable correlation to focus error that can be employed to determine focus error for subsequently-produced first test patterns and second test patterns having the same configuration as the patterns used to establish the pre-determined correlation. In embodiments, the pre-determined correlation is provided prior to conducting the method. In other embodiments, the pre-determined correlation is produced in accordance with the method.

In various embodiments, relative shift data is produced through other measurements of non-telecentricity-induced shift between the first test pattern and the second test pattern. For example, instead of measuring and comparing the shift of features within the respective test patterns, other shift comparisons include shift between a feature of the first test pattern and a feature of the second test pattern at one location and between another feature of the first test pattern and another feature of the second test pattern at another location, shift between respective features of the first test pattern and the second test pattern and a common reference feature, or shift between a feature of the first test pattern and an overlaid reference feature in a first region and a feature of the second test pattern and an overlaid reference feature in a second region, where the reference features in the first region and the second region are formed at the same pitch.

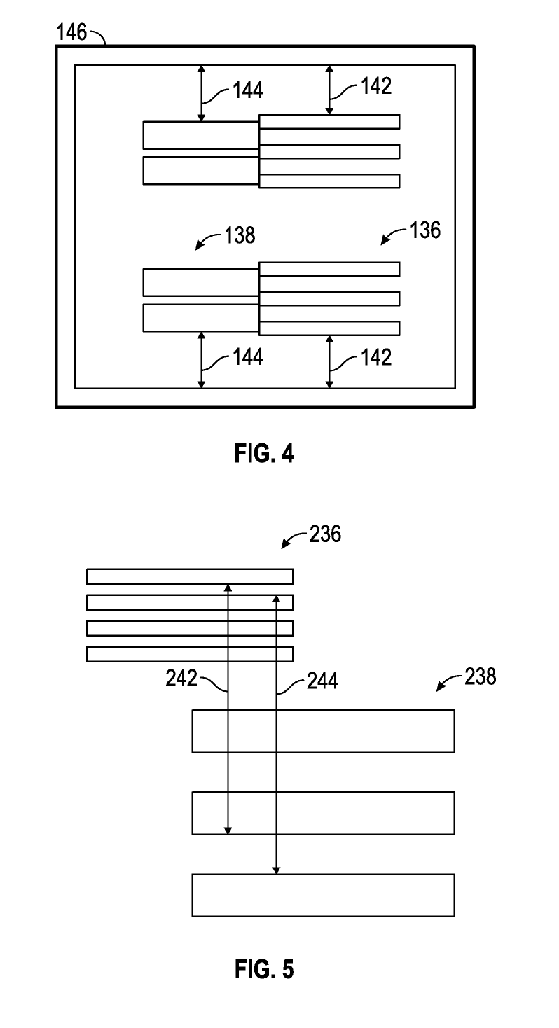

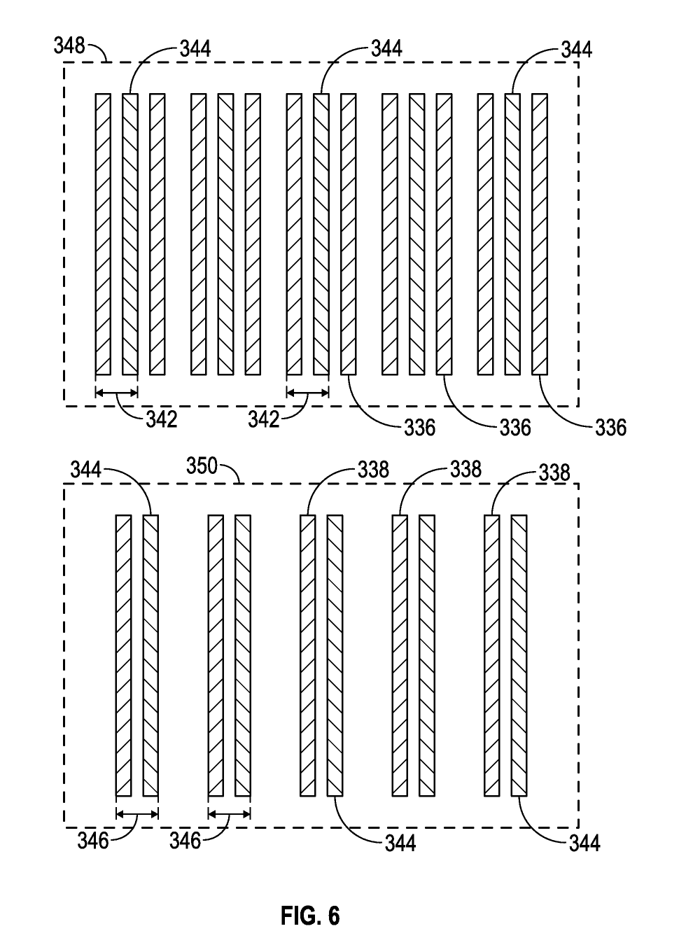

Various relative configurations of the first test pattern and the second test pattern are possible depending upon the particular shift comparisons that are measured. In an embodiment and referring to FIG. 2, the first test pattern 36 and the second test pattern 38 are shown with the respective features thereof coaxially formed, with such configuration suitable for comparing shift between features of the respective patterns 36, 38 by measuring a difference in spacing between pattern features of the first test pattern 36 (measurement 42) and pattern features in the second test pattern 38 (measurement 44). In another embodiment and referring to FIG. 4, first test pattern 136 and second test pattern 138 are patterned within a reference feature 146 (e.g., a box) that provides a point of reference for both the first test pattern 136 and the second test pattern 138. In this embodiment, non-telecentricity induced shift of first test pattern 136 and second test pattern 138 is measured by measuring a difference in spacing between a feature in the first test pattern 136 and the reference feature 146 (measurement 142) and a feature in the second test pattern 138 and the reference feature 146 (measurement 144). In another embodiment and referring to FIG. 5, first test pattern 236 and second test pattern 238 are shown with the respective features thereof formed in parallel orientation with each other and with the respective features of the first test pattern 236 and second test pattern 238 at least partially transversely overlapping, with such configuration suitable for comparing shift between features of the respective patterns 236, 238 by measuring a difference in spacing between a feature of the first test pattern 236 and a feature of the second test pattern 238 at one location (measurement 242) and between another feature of the first test pattern 236 and another feature of the second test pattern 238 at another location (measurement 244). In another embodiment and referring to FIG. 6, a first region 348 includes first test pattern 336 and a reference pattern 344 patterned at a different pitch from the first pitch, wherein the first test pattern 336 and a portion of the reference pattern 344 are patterned in overlaying relationship, i.e., the first test pattern 336 and the reference pattern 344 are printed in the same area and are complementary to each other. A second region 350 includes second test pattern 338 and another portion of the reference pattern 344 patterned in overlaying relationship. In this embodiment, the non-telecentricity induced shift of the first test pattern 336 and the second test pattern 338 is measured by measuring a difference in spacing between a pattern feature of the first test pattern 336 and the reference pattern 344 (measurement 342) and a pattern feature of the second test pattern 338 and the reference pattern 344 (measurement 346).

The non-telecentricity induced shift of the first test pattern and the second test pattern may be measured between fabrication stages during integrated circuit formation on the wafer. For example, referring again to FIG. 1, the measurement device 40 may be located immediately after one fabrication stage during integrated circuit formation and before another fabrication stage. Focus of the ultraviolet light may be adjusted based upon comparison of the relative shift data to the pre-determined correlation between the non-telecentricity induced shift of the first test pattern and the second test pattern as a function of focus error. In this manner, focus shift error may be expediently identified and appropriately adjusted during integrated circuit fabrication to minimize production of out-of-specification products.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention. It being understood that various changes may be made in the function and arrangement of elements described in an exemplary embodiment without departing from the scope of the invention as set forth in the appended claims.

What is claimed is:

1. A method of controlling focus of ultraviolet light produced by a lithographic imaging system, wherein the method comprises:
providing a wafer having a resist film disposed thereon;
patterning the resist film through illumination of a lithography mask with ultraviolet light at an off-normal incidence angle with a first test pattern formed at a first pitch and a second test pattern formed at a second pitch different from the first pitch;
measuring a non-telecentricity induced shift of the first test pattern and the second test pattern to produce relative shift data using a measurement device;
adjusting focus of the ultraviolet light based upon comparison of the relative shift data to a pre-determined correlation between the non-telecentricity induced shift of the first test pattern and the second test pattern as a function of focus error.

2. The method of claim 1, further comprising patterning an array of first test patterns and second test patterns with known focus errors to produce the pre-determined correlation between the non-telecentricity induced shift of the first test pattern and the second test pattern as a function of focus error.

3. The method of claim 2, wherein patterning the array of first test patterns and second test patterns comprises patterning the array of first test patterns and second test patterns on a focus meander wafer.

4. The method of claim 1, wherein providing the wafer comprises providing a product wafer having the resist film disposed thereon.

5. The method of claim 1, wherein providing the wafer comprises providing the wafer having the resist film disposed thereon with the resist film having a thickness of less than about 60 nm.

6. The method of claim 1, wherein patterning the resist film comprises patterning device features as the first test pattern and the second test pattern.

7. The method of claim 1, wherein patterning the resist film comprises patterning the first test pattern and the second test pattern as independent features from patterned device features.

8. The method of claim 1, wherein patterning the resist film comprises patterning the resist film through extreme ultraviolet lithography.

9. The method of claim 1, wherein patterning the resist film with the first test pattern at the first pitch and the second test pattern at the second pitch comprises patterning the resist film with the first pitch is different from the second pitch by a magnitude of at least 3×.

10. The method of claim 1, wherein measuring the non-telecentricity induced shift of the first test pattern and the second test pattern comprises measuring a difference in spacing between pattern features of the first test pattern and pattern features in the second test pattern.

11. The method of claim 1, wherein measuring the non-telecentricity induced shift of the first test pattern and the second test pattern comprises measuring a difference in spacing between a feature in the first test pattern and a reference feature and a feature in the second test pattern and the reference feature.

12. The method of claim 1, wherein a first region includes the first test pattern and a reference pattern patterned at a different pitch from the first pitch, wherein the first test pattern and a portion of the reference pattern are patterned in overlaying relationship, wherein a second region includes the second test pattern and another portion of the reference pattern patterned in overlaying relationship, and wherein measuring the non-telecentricity induced shift of the first test pattern and the second test pattern comprises measuring a difference in spacing between a pattern feature of the first test pattern and the reference pattern and a pattern feature of the second test pattern and the reference pattern.

13. The method of claim 1, wherein measuring the non-telecentricity induced shift of the first test pattern and the second test pattern comprises measuring the non-telecentricity induced shift of the first test pattern and the second test pattern using a scanning electron micrograph device.

14. The method of claim 1, wherein measuring the non-telecentricity induced shift of the first test pattern and the second test pattern comprises measuring the non-telecentricity induced shift of the first test pattern and the second test pattern using an overlay measurement device.

15. The method of claim 1, wherein measuring the non-telecentricity induced shift of the first test pattern and the second test pattern comprises measuring the non-telecentricity induced shift of the first test pattern and the second test pattern using a scatterometry overlay metrology device.

16. The method of claim 1, wherein measuring the non-telecentricity induced shift of the first test pattern and the second test pattern comprises measuring the non-telecentricity induced shift of the first test pattern and the second test pattern between fabrication stages during integrated circuit formation on the wafer.

17. An apparatus for forming an integrated circuit, wherein the apparatus comprises:
a lithographic imaging system configured to pattern a resist film on a wafer through illumination of a lithography mask at an off-normal incidence angle;
a controller programmed to control focus of ultraviolet light produced by the lithographic imaging system, wherein the controller is programmed with instructions to:
pattern the resist film on the wafer using the ultraviolet light produced by the lithographic imaging system through illumination of the lithography mask at the off-normal incidence angle with a first test pattern formed at a first pitch and a second test pattern formed at a second pitch different from the first pitch;
analyze relative shift data obtained from measuring non-telecentricity induced shift of the first test pattern and the second test pattern; and
adjust focus of the ultraviolet light based upon comparison of the relative shift data to a pre-determined correlation between the non-telecentricity induced shift of the first test pattern and the second test pattern as a function of focus error; and
a measurement device configured to measure the non-telecentricity induced shift of the first test pattern and the second test pattern to produce the relative shift data.

18. The apparatus of claim 17, wherein the measurement device is chosen from a scanning electron micrograph device, an overlay measurement device, or a scatterometry overlay metrology device.

19. The apparatus of claim 17, wherein the lithographic imaging system comprises an extreme ultraviolet lithographic imaging system.

20. A controller programmed to control focus of ultraviolet light produced by a lithographic imaging system, wherein the controller is programmed with instructions to:
pattern a resist film on a wafer using the ultraviolet light produced by the lithographic imaging system through illumination of a lithography mask at an off-normal incidence angle with a first test pattern formed at a first pitch and a second test pattern formed at a second pitch different from the first pitch;
analyze relative shift data obtained from measuring non-telecentricity induced shift of the first test pattern and the second test pattern; and
adjust focus of the ultraviolet light based upon comparison of the relative shift data to a pre-determined correlation between the non-telecentricity induced shift of the first test pattern and the second test pattern as a function of focus error.
